(19) United States
(12) Patent Application Publication
(10) Pub. No.: US 2025/0211183 A1
(43) Pub. Date: Jun. 26, 2025

(54) INSTRUMENTATION AMPLIFIER AND SIGNAL DETECTION SYSTEM

(71) Applicant: Silergy Semiconductor Technology (Hangzhou) LTD, Hangzhou, Zhejiang Province (CN)

(72) Inventors: Feng Chen, Hangzhou (CN); Ji Ma, Hangzhou (CN)

(21) Appl. No.: 18/971,313

(22) Filed: Dec. 6, 2024

(30) Foreign Application Priority Data
Dec. 20, 2023 (CN) 202311764825.6

(51) Int. Cl. H03F 3/393; H03F 1/26; H03F 1/56; H03F 3/45

(52) U.S. Cl. CPC H03F 3/393; H03F 1/26; H03F 1/56; H03F 3/45475; H03F 3/45973; H03F 2200/168; H03F 2200/261; H03F 2200/271; H03F 2200/375; H03F 2200/459

(57) ABSTRACT

An instrumentation amplifier can include: an input port configured to receive a sensor signal; a first-stage amplifier configured to amplify the sensor signal to obtain a first intermediate signal; a first high-pass filter circuit, having input terminals coupled to output terminals of the first-stage amplifier, and being configured to eliminate a signal that is in the first intermediate signal and associated with an offset voltage of the first-stage amplifier, in order to obtain a second intermediate signal; a first chopper, having input terminals coupled to output terminals of the first high-pass filter circuit, and being configured to perform chopper modulation and demodulation on the second intermediate signal to obtain a third intermediate signal; and a second-stage amplifier, having input terminals coupled to output terminals of the first chopper, and being configured to amplify the third intermediate signal to generate an output signal.

### RELATED APPLICATIONS

This application claims the benefit of Chinese Patent Application No. 202311764825.6, filed on Dec. 20, 2023, which is incorporated herein by reference in its entirety.

### FIELD OF THE INVENTION

The present invention generally relates to the field of power electronics, and more particularly to instrumentation amplifiers and signal detection systems.

### BACKGROUND

An instrumentation amplifier is a differential voltage amplifier with features such as high common-mode rejection ratio, high input impedance, low noise, low linear error, low offset drift, flexible gain setting, and ease of use, thus making it widely used in data acquisition and sensor signal amplification. It is popular in high-speed signal conditioning, medical instruments, and high-end audio equipment. In terms of sensor signal amplification, both the sensor and the amplifier may have offset voltages. The offset voltage can cause low system accuracy and average common-mode rejection ratio. Therefore, removing the offset voltage is important for the accuracy of the instrumentation amplifier.

### BRIEF DESCRIPTION OF THE DRAWINGS

FIG. 1 is a schematic block diagram of a first example instrumentation amplifier.

FIG. 2 is a schematic block diagram of a second example instrumentation amplifier.

FIG. 3 is schematic block diagram of an example signal detection system, in accordance with embodiments of the present invention.

FIG. 4 is a schematic block diagram of an example driving method of the sensor, in accordance with embodiments of the present invention.

FIG. 5 is a waveform diagram of the example sensor, in accordance with embodiments of the present invention.

FIG. 6 is a schematic block diagram of a first example instrumentation amplifier, in accordance with embodiments of the present invention.

FIG. 7 is a schematic block diagram of an example active resistor, in accordance with embodiments of the present invention.

FIG. 8 is an equivalent circuit diagram of the first instrumentation amplifier, in accordance with embodiments of the present invention.

FIG. 9 is a waveform diagram of the equivalent circuit of the first instrumentation amplifier, in accordance with embodiments of the present invention.

FIG. 10 is another equivalent circuit of the first instrumentation amplifier, in accordance with embodiments of the present invention.

FIG. 11 is a waveform diagram of the equivalent circuit of the first instrumentation amplifier of FIG. 10, in accordance with embodiments of the present invention.

FIG. 12 is a schematic block diagram of a second example instrumentation amplifier, in accordance with embodiments of the present invention.

FIG. 13 is a waveform diagram of the equivalent circuit of the second instrumentation amplifier, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention. With the development of economy, batteries have become one of the important clean energy sources in today's society. In general application, each battery pack consists of a plurality of battery modules connected in series, and each battery module consists of a plurality of battery cells or batteries connected in series.

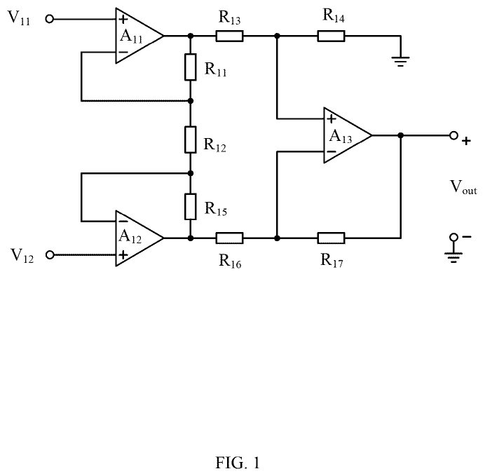

In one approach for removing offset voltage, a ripple reduction loop (RRL) circuit can be used to eliminate ripples caused by the offset voltage. However, the RRL circuit may be relatively complex and require relatively large area and power consumption. Referring now to FIG. 1, shown is a schematic block diagram of a first example instrumentation amplifier. In this example, the instrumentation amplifier can include operational amplifiers A₁₁, A₁₂, A₁₃ and multiple resistors. Here, the multiple resistors include resistors R₁₁-R₁₇. The non-inverting input terminal of operational amplifier A₁₁ may receive input signal V₁₁, and resistor R₁₁ can connect between the inverting input terminal and the output terminal of operational amplifier A₁₁. The non-inverting input terminal of operational amplifier A₁₂ may receive input signal V₁₂, and resistor R₁₁ can connect between the inverting input terminal and the output terminal of operational amplifier A₁₂. Resistors R₁₃ and R₁₄ can connect in series between the output terminal of operational amplifier A₁₁ and a ground terminal. Resistors R₁₆ and R₁₇ can connect in series between the output terminal of operational amplifier A₁₂ and the output terminal of operational amplifier A₁₃. The non-inverting input terminal of operational amplifier A₁₃ can connect to a common node between resistors R₁₃ and R₁₄, and the inverting input terminal of operational amplifier A₁₃ can connect to a common node between resistors R₁₆ and R₁₇. Resistor R₁₂ can connect between resistors R₁₁ and R₁₅.

In this example, when input signals V₁₁ and V₁₂ are common-mode signals, output signal Vₒᵤₜ of operational amplifier A13 is 0. The circuit structure shown in FIG. 1 is relatively simple, and the area and power consumption are relatively low. However, the noise performance may not be ideal, and the offset voltage caused by the pre-stage sensor and the amplifier itself may not be removed, thus resulting in low system accuracy and general common-mode rejection ratio.

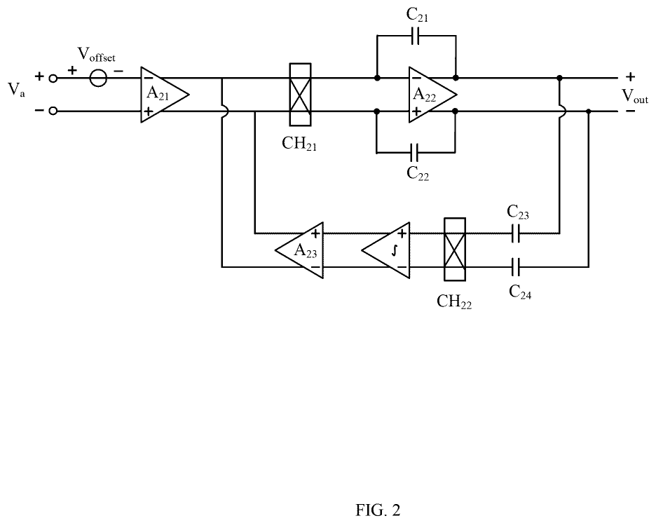

Referring now to FIG. 2, shown is a schematic block diagram of a second example instrumentation amplifier. In this particular example, the instrumentation amplifier can include operational amplifiers A₂₁, A₂₂ and A₂₃, an integrator, capacitors C₂₁, C₂₂, C₂₃ and C₂₄, and choppers CH₂₁ and CH₂₂. Here, operational amplifier A₂₁ is the first-stage amplifier, operational amplifier A₂₂ is the second-stage amplifier. Operational amplifier A₂₃, the integrator connected between operational amp A₂₃ and chopper CH₂₂, capacitors C₂₃ and C₂₄, and chopper CH₂₂ may form a ripple reduction loop (RRL) circuit. In one example, after input signal Va is amplified by operational amplifier A₂₁, the amplified signal can be modulated and demodulated by chopper CH₂₁, and then the output signal of chopper CH₂₁ may be amplified again by operational amplifier A₂₂. Capacitors C₂₁ and C₂₂ can respectively connect between one input terminal and the output terminal of operational amplifier A₂₂, and may form a Miller compensation amplifier with operational amplifier A₂₂ to improve the gain of the high frequency signal. Since operational amplifier A₂₁ itself has a non-zero offset voltage (equivalent to voltage V_{offset} in FIG. 2), the output signal of operational amplifier A₂₁ can include both the amplification signal of input signal Va and the offset voltage of operational amplifier A₂₁.

After the offset voltage of operational amplifier A₂₁ is passed through chopper CH₂₁ and operational amplifier A₂₂, a ripple signal at the output terminal of the instrumentation amplifier may be generated by the offset voltage of operational amplifier A₂₁. The RRL circuit can sample the output signal including the ripple signal at the output terminal of the instrumentation amplifier, and then the sampled signal may pass through chopper CH₂₂ to obtain the DC value of the ripple signal. After the DC value of the ripple signal is integrated by the integrator, a compensation voltage may be generated at the input terminals of operational amplifier A₂₃. The compensation voltage can compensate the offset voltage of operational amplifier A₂₁ to reduce the amplitude of the ripple signal introduced by the offset voltage. In addition, the offset voltage of operational amplifier A₂₂ can be suppressed by the gain of operational amplifier A₂₁, so it can effectively be ignored. Therefore, this embodiment can realize the function of removing the offset voltage. However, this approach may only remove the offset voltage of the operational amplifier, not the offset voltage of the front-stage sensor. In addition, the offset voltage can be removed through the RRL circuit, which is relatively complex, and the area and power consumption are relatively large.

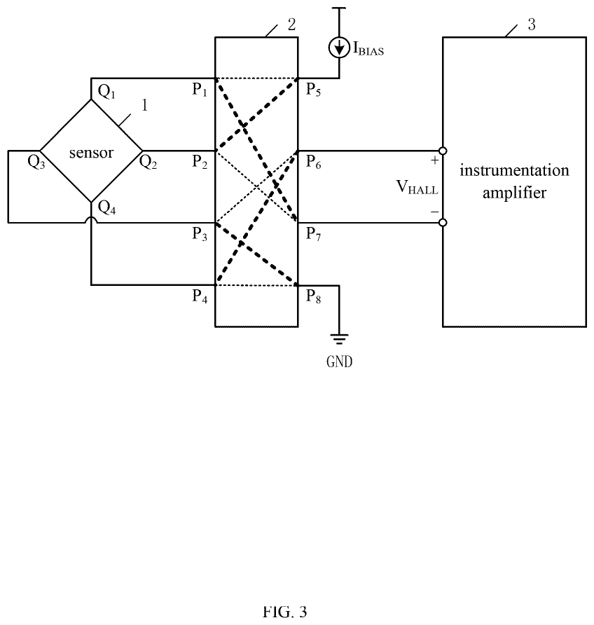

Referring now to FIG. 3, shown is schematic block diagram of an example signal detection system, in accordance with embodiments of the present invention. In this particular example, the signal detection system can include sensor 1, switching circuit 2, and instrumentation amplifier 3. Switching circuit 2 may obtain a sensor signal corresponding to the output voltage of sensor 1, and instrumentation amplifier 3 can generate an output signal according to the sensor signal, where the output signal may characterize the output voltage of sensor 1. For example, the sensor signal can be an output voltage, and may be generated by driving sensor 1 by switching circuit 2. In this example, sensor 1 can be various types of sensors (e.g., a temperature sensor, a pressure sensor, a Hall sensor, etc.). Here, a Hall sensor is taken as an example to illustrate, and sensor 1 can include four ports Q1, Q₂, Q₃, and Q₄.

In one embodiment, switching circuit 2 may perform chopper modulation and demodulation on the DC output voltage of the sensor, in order to generate a sensor signal in the form of a square wave signal. For example, switching circuit 2 can include multiple switches and multiple ports, e.g., switching circuit 2 can include eight ports P₁-P₈. Ports P₁-P₄ can connect to four ports Q₁-Q₄ of sensor 1, respectively, port P₅ may receive bias current I_{BIAS}, port P₈ can connect to ground terminal GND, and ports P₆ and P₇ can be read-out ports connected to the instrumentation amplifier. When the Hall sensor operates normally, an excitation source may be applied to the two ports in any direction, and the two ports in the other direction can read the output voltage of the sensor. By turning on and off multiple switches in switching circuit 2, the ports coupled to the excitation source and the ports coupled to the readout port in the sensor can be constantly switched between the two driving modes. For example, the four ports of the Hall sensor can continuously switch to different excitation sources or readout ports with operating frequency fs.

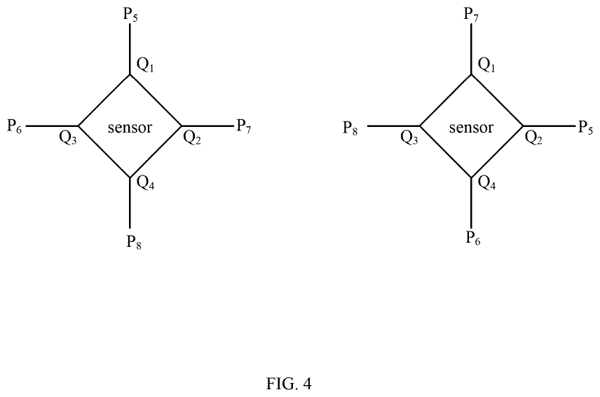

Referring now to FIG. 4, shown is a schematic block diagram of an example driving mode of the sensor, in accordance with embodiments of the present invention. Two driving modes of the sensor are shown in this particular example, and the schematic diagram on the left side is the first driving mode. Port Q₁ of the sensor can connect to port P₅, port Q₂ of the sensor can connect to port P₇, port Q₃ of the sensor can connect to port P₆, and port Q₄ can connect to port P₈. The schematic diagram on the right side is the second driving mode, port Q₁ of the sensor can connect to port P₇, port Q₂ of the sensor can connect to port P₅, port Q3 of the sensor can connect to port P₈, and port Q₄ of the sensor can connect to port P₆.

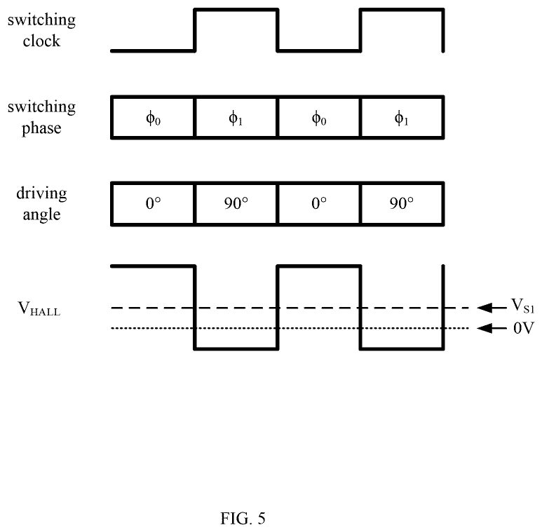

Referring now to FIG. 5, shown is a waveform diagram of the example sensor, in accordance with embodiments of the present invention. In this particular example, the switching clock is a square wave signal with a predetermined frequency. When the switching clock is low, the switching phase is φ₀, and thus the sensor is the first driving mode shown on the left side of FIG. 4. The driving angle of the sensor is 0°, and sensor signal V_{HALL} is greater than 0. When the switching clock is high, the switching phase is φ₁, and thus the sensor is the second driving mode shown on the right side of FIG. 4. The driving angle of the sensor is 90°, and sensor signal V_{HALL} is less than 0. In addition, due to the existence of offset voltage V_{S1} of the sensor, the sensor signal may be shifted the amount of offset voltage V_{S1} upward from 0V as a whole. In other words, in the sensor signal read by the switching circuit, the offset voltage of the sensor itself is a DC signal, the output voltage of the sensor may become a high-frequency signal, and the high-frequency signal can be in the form of a square wave.

The frequency of the square wave may be the same as frequency fs of the switching clock, and also the same as the operating frequency of the system, such that subsequent signal processing can easily separate the offset voltage from the output voltage. In some embodiments, operating frequency fs can be selected to be more than twice the bandwidth of the amplifier. In this particular example, since the output voltage of the sensor and sensor signal V_{HALL} are relatively small, the output voltage of the sensor can be amplified by instrumentation amplifier 3 to a reading range suitable for the instrument and the display.

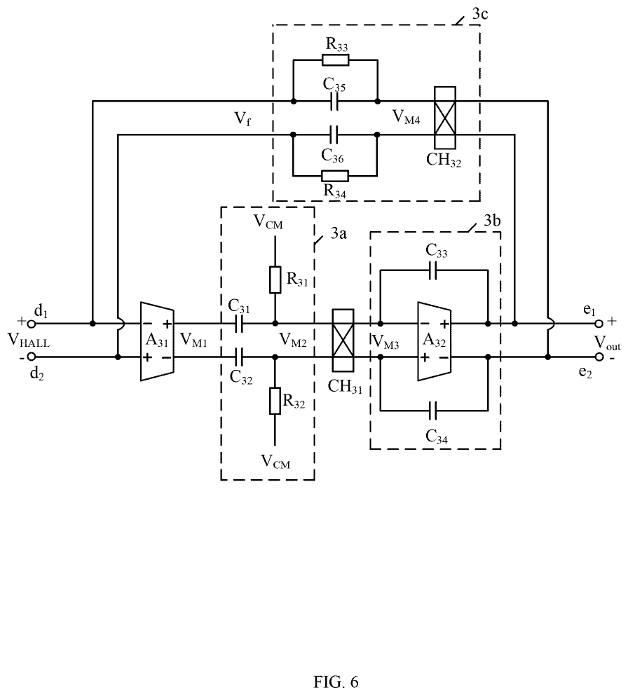

Referring now to FIG. 6, shown is a schematic block diagram of a first example instrumentation amplifier, in accordance with embodiments of the present invention. In this particular example, the instrumentation amplifier can include an input port, first-stage amplifier A₃₁, high-pass filter circuit 3a, chopper CH₃₁, second-stage amplifier 3b, feedback circuit 3c, and an output port. The input port may receive sensor signal V_{HALL}. Amplifier A₃₁ can amplify sensor signal V_{HALL} to obtain intermediate signal V_{M1}. The input terminals of high-pass filter circuit 3a can connect with the output terminals of first-stage amplifier A₃₁, and high-pass filter circuit 3a and may eliminate the signal included in first intermediate signal V_{M1} and associated with the offset voltage of first-stage amplifier A₃₁ to obtain intermediate signal V_{M2}.

The input terminals of first chopper CH₃₁ can connect with the output terminals of first high-pass filter circuit 3a, and first chopper CH₃₁ may perform chopper modulation and demodulation on second intermediate signal V_{M2} to obtain third intermediate signal V_{M3}. The input terminals of second-stage amplifier 3b can connect to the output terminals of first chopper CH₃₁, and second-stage amplifier 3b may amplify third intermediate signal V_{M3} to generate output signal Vₒᵤₜ. Feedback circuit 3c can connect between the output terminals of second-stage amplifier 3b and the input terminals of first-stage amplifier A₃₁, and may feedback output signal Vₒᵤₜ to the input terminals of first-stage amplifier A₃₁.

In one embodiment, the instrumentation amplifier can include a control circuit that can generate a control signal to control the operating frequency of the first chopper and/or the second chopper to perform chopper modulation and demodulation. The input port can include positive input terminal di and negative input terminal d₂, and may receive sensor signal V_{HALL}. The output port can include positive output terminal e₁ and negative output terminal e₂, and can generate output signal Vₒᵤₜ.

In one embodiment, first-stage amplifier A₃₁ can be a transconductance operational amplifier, including two input terminals and two output terminals. The inverting input terminal and the non-inverting input terminal of first-stage amplifier A₃₁ may respectively connect to negative output terminal e₂ and positive output terminal e₁ through feedback circuit 3c. Amplifier A₃₁ can receive sensor signal V_{HALL} and feedback signal V_{f} output by feedback circuit 3c, and may perform amplifying process on sensor signal V_{HALL} and feedback signal V_{f}, to generate intermediate signal V_{M1} through the inverting output terminal and the non-inverting output terminal. In some embodiments, stage amplifier A₃₁ may have larger gain G1 (e.g., gain G1 can be set to be greater than 100).

It should be noted that the example of FIG. 6 is illustrated by the inverting input terminal of amplifier A₃₁ being connected to negative output terminal e₂ through feedback circuit 3c, and the non-inverting input terminal being connected to positive output terminal e₁ through feedback circuit 3c, but other connection arrangements can be supported in certain embodiments. In addition, feedback circuit 3c can include chopper CH₃₂ that can alternately output the input signal forward or reverse at a predetermined operating frequency. If the two terminals on the right side of second chopper CH₃₂ are input terminals, and the two terminals on the left side are output terminals, one of the two input terminals can connect to positive output terminal e₁, and the other of the two input terminals can connect to negative output terminal e₂. Similarly, one of the two output terminals can connect to the inverting input terminal of first-stage amplifier A₃₁, and the other of the two output terminals can connect to the non-inverting input terminal of first-stage amplifier A₃₁. Therefore, according to the connection mode, output signal Vout may be modulated into a predetermined format by chopper CH₃₂ and fed back to first stage amplifier A₃₁. In this example, first-stage amplifier A₃₁ only shows a single component, but the first-stage amplifier can include multiple components in certain embodiments.

The input terminals of high-pass filter circuit 3a can connect to the output terminals of first-stage amplifier A₃₁, and high-pass filter circuit 3a may eliminate the signal associated with the offset voltage of first-stage amplifier A₃₁ and included in first intermediate signal V_{M1} to obtain intermediate signal V_{M2}. High-pass filter circuit 3a can include first capacitors and first impedance circuits. The first capacitor can connect between the one output terminal of amplifier A₃₁ and one input terminal of chopper CH₃₁. The first impedance circuit and the first capacitor can connect in series between the output terminal of first stage amplifier A₃₁ and the reference terminal. For example, high-pass filter circuit 3a can include capacitors C₃₁ and C₃₂, and impedance circuits R₃₁ and R₃₂. Capacitor C₃₁ can connect between the non-inverting output terminal of amplifier A₃₁ and the first input terminal of chopper CH₃₁. One terminal of impedance circuit R₃₁ can connect to the common end of capacitor C₃₁ and chopper CH₃₁, and the other terminal of first circuit R₃₁ can connect to the reference terminal. Capacitor C₃₂ can connect between the inverting output terminal of amplifier A₃₁ and the second input terminal of chopper CH₃₁. One terminal of impedance circuit R₃₂ can connect to the common end of capacitor C₃₂ and chopper CH₃₁, and the other terminal of impedance circuit R₃₂ can connect to the reference terminal.

Here, the reference terminal may provide a reference voltage (common mode voltage) V_{CM}, and reference voltage V_{CM} can be set according to the particular application. In one example, the reference terminal is the ground terminal, and reference voltage V_{CM} is 0. In another example, switching circuit 2 and instrumentation amplifier 3 may be integrated in one chip, and reference voltage V_{CM} can be equal to the supply voltage of the chip multiplied by a proportional coefficient. Since the first stage amplifier itself may have an offset voltage, the offset voltage is a DC component, so intermediate signal V_{M1} may have both DC and AC components. Therefore, the first capacitor and the first impedance circuit can be set as a high-pass filter to connect to the output terminals of amplifier A₃₁. Because the characteristic of the capacitor is isolated from the DC, the offset voltage of the first-stage amplifier may not pass, and the effective AC component can pass, such that high-pass filter circuit 3a can eliminate the signal associated with the offset voltage of first-stage amplifier A₃₁ and included in intermediate signal V_{M1}. In another example, the first impedance circuit is a resistive element. In yet another example, the first impedance circuit is an active resistor to significantly reduce the resistance area and cost.

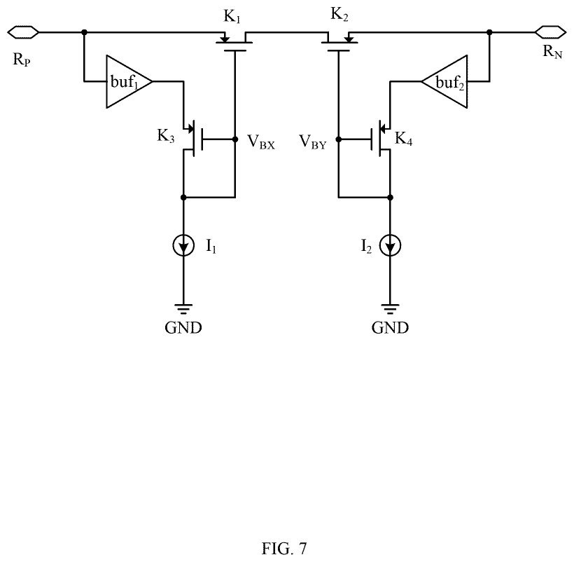

Referring now to FIG. 7, shown is a schematic block diagram of an example active resistor, in accordance with embodiments of the present invention. The active resistor can include terminal R_{P}, terminal R_{N}, transistor K₁, transistor K₂, transistor K₃, transistor K₄, buffer buf₁, buffer buf₂, current source I₁, and current source I₂. Transistors K₁ and K₂ can connect in series between terminals R_{P} and R_{N}, the source of transistor K₁ can connect to terminal R_{P}, the source of transistor K₂ can connect with terminal R_{N}, and the drain of transistor K₁ can connect with the drain of transistor K₂. Therefore, transistors K₁ and K₂ can connect in series between terminals R_{P} and R_{N} to form the main body of the active resistor. Buffer buf₁, transistor K₃, and current source I₁ can connect in series between terminal R_{P} and ground terminal GND, where the input terminal of buffer buf₁ can connect to terminal R_{P}, the source of transistor K₃ can connect to the output terminal of buffer buf₁, current source I₁ can connect between the drain of transistor K₃ and ground terminal GND, and the control (or gate) terminals of transistors K₁ and K₃ can connect to current source I₁. Buffer buf₂, transistor K₄, and current source I₂ can connect in series between terminal R_{N} and ground terminal GND, where the input terminal of buffer buf₂ can connect with terminal R_{N}, the source of transistor K₄ can connect with the output terminal of buffer buf₂, current source I₂ can connect between the drain of transistor K₄ and ground terminal GND, and the control (or gate) terminals of transistors K₂ and K₄ can connect with second current source I₂.

For the first structure including terminal R_{P}, transistor K₁, transistor K₃, buffer buf₁, and current source I₁, transistor K₃ may generate bias voltage V_{BX} under the bias of the first bias current generated by current source I₁, such that transistor K₁ may operate in the sub-threshold region. For example, buffer buf₁ can prevent a resistive load effect of transistor K₃ directly on terminal R_{P}. Under the bias of the first bias current, bias voltage V_{BX} can be generated at the high potential terminal of current source I₁. Bias voltage V_{BX} can control the operation state of transistors K₁ and K₃. Thus, by reasonably designing the size of transistors K₁ and K₃, and the size of the first bias current, transistor K₁ can operate in the sub-threshold region under the control of bias voltage V_{BX}. When the transistor operates in the sub-threshold region, a very small current may flow through the transistor, such as may equivalent to a large resistance.

For the second structure including port R_{N}, transistor K₂, transistor K₄, buffer buf₂, and current source I₂, transistor K₄ may generate bias voltage V_{BY} under the bias of the second bias current generated by current source I₂, such that transistor K₂ operates in the sub-threshold region. For example, buffer buf₂ can prevent the resistive load effect of transistor K₄ directly on terminal R_{N}. Under the bias of the second bias current, bias voltage V_{BY} can be generated at the high potential end of current source I₂. Bias voltage V_{BY} can control the operation state of transistors K₂ and K₄. By reasonably designing the size of transistors K₂ and K₄ and the size of the second bias current, transistor K₂ may operate in the sub-threshold region under the control of bias voltage V_{BY}. When the transistor operates in the sub-threshold region, a relatively small current may flow through the transistor, thus being equivalent to a large resistance.

When the active resistor shown in FIG. 7 is applied in the instrumentation amplifier described in FIG. 6, one of terminals R_{P} and R_{N} can be coupled to the common end of the first capacitor (e.g., capacitor C₃₁ or C₃₂) and the first chopper, and the other one of terminals R_{P} and R_{N} can connect to the reference terminal to receive common mode signal V_{CM}. In this way, a larger resistance value with a smaller area can be provided through the active resistor. By adding a buffer, there may be no driving capability requirement for the nodes at both terminals of the first impedance circuit, such that application limits may be reduced and the range expanded.

In particular embodiments, the input terminals of chopper CH₃₁ can connect to the output terminals of high-pass filter circuit 3a, and chopper CH₃₁ may perform chopper modulation and demodulation on intermediate signal V_{M2} to obtain intermediate signal V_{M3}. Chopper CH₃₁ can be a chopper modem, and may alternately output the input signal forward or reverse at a predetermined operating frequency, thereby performing chopper modulation and demodulation on intermediate signal V_{M2} to obtain intermediate signal V_{M3}. Therefore, the chopper modulation and demodulation can be performed by chopper CH₃₁, the signal passing through amplifier 3b may be an un-modulated signal, and the bandwidth requirement of second-stage amplifier 3b can be reduced.

In particular embodiments, other connection modes of chopper CH₃₁ can be supported. Chopper CH₃₁ may alternately output the input signal forward or reverse at a predetermined operating frequency. When the two terminals on the left side of chopper CH₃₁ are the input terminals and the two terminals on the right side are the output terminals, one of the two input terminals can connect to the common end of resistor R₃₁ and capacitor C₃₁, and the other of the two input terminals can connect to the common end of resistor R₃₂ and capacitor C₃₂. Similarly, one of the two output terminals can connect to the inverting input terminal of operational amplifier A₃₂, and the other of the two output terminals can connect to the non-inverting input terminal of operational amplifier A₃₂. Therefore, according to the particular connection mode, chopper CH₃₁ may be controlled to modulate and demodulate intermediate signal V_{M2} into a predetermined format to obtain intermediate signal V_{M3}.

The input terminals of amplifier 3b can connect with the output terminals of chopper CH₃₁, and stage amplifier 3b may amplify intermediate signal V_{M3} to generate output signal Vout. In certain embodiments, stage amplifier 3b can include operational amplifier A₃₂ and capacitors C₃₃ and C₃₄, as shown in FIG. 6. Operational amplifier A₃₂ can be a transconductance operational amplifier, including two input terminals and two output terminals. Capacitor C₃₃ can connect between the inverting output terminal and the non-inverting output terminal of operational amplifier A₃₂, and capacitor C₃₄ can connect between the non-inverting input and inverting output terminals of operational amplifier A₃₂. Thus, operational amplifier A₃₂ and capacitors C₃₃ and C₃₄ may form a Miller compensation amplifier stage. The circuit bandwidth of the Miller compensation amplifier stage can be relatively narrow, which may provide a higher gain for the un-modulated signal and a smaller gain for the offset voltage modulated to the predetermined frequency, thereby further reducing the amplitude of the offset voltage in output signal Vout.

Feedback circuit 3c can connect between the output terminals of amplifier 3b and the input terminals of amplifier A₃₁, and may feedback output signal Vout to amplifier A₃₁. In certain embodiments, feedback circuit 3c can include chopper CH₃₂, a third capacitor, and a third resistor. The input terminals of chopper CH₃₂ can connect to the output terminals of amplifier 3b, and chopper CH₃₂ can perform chopper modulation and demodulation on output signal Vout to obtain intermediate signal V_{M4}. Chopper CH₃₂ can be a chopper modem, and may alternately output the input signal forward or reverse at a predetermined operating frequency, and to chopper output signal Vout to obtain intermediate signal V_{M4}. The third resistor can connect in parallel with the third capacitor to form the first circuit. The first circuit can connect between the output terminal of chopper CH₃₂ and the input terminal of amplifier A₃₁, and may feedback intermediate signal V_{M4} to amplifier A₃₁. Here, the number of the third capacitor and the third resistor is 2, respectively, such as third capacitors C₃₅ and C₃₆, and third resistors R₃₃ and R₃₄ as shown in FIG. 7.

In some embodiments, the instrumentation amplifier also can include a control circuit that may generate a control signal to control the operating frequency of chopper CH₃₁ and/or chopper CH₃₂ for chopper modulation and demodulation. The frequency of the control signal can be the same as the frequency of the switching clock of the switching circuit.

The instrumentation amplifier of particular embodiments may receive the sensor signal through the input port. The first-stage amplifier can amplify the sensor signal to obtain the first intermediate signal. The first high-pass filter circuit may eliminate the signal associated with the offset voltage of the first-stage amplifier and included in the first intermediate signal to obtain the second intermediate signal. The first chopper can perform chopper modulation and demodulation on the second intermediate signal to obtain the third intermediate signal. The second-stage amplifier may amplify the third intermediate signal to generate an output signal. The feedback circuit can feed the output signal back to the first-stage amplifier. Therefore, the offset voltage of the first stage amplifier can be eliminated by the first high-pass filter circuit, which may reduce the complexity of the circuit, the circuit area, and power consumption.

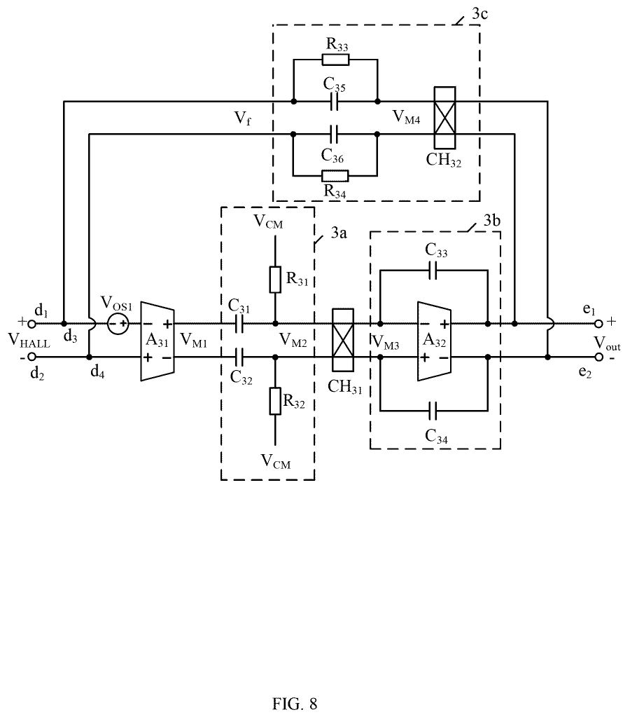

Referring now to FIG. 8, shown is an equivalent circuit diagram of the first example instrumentation amplifier, in accordance with embodiments of the present invention. In this particular example, the first stage amplifier with the offset voltage can be equivalent to voltage source V_{OS1} and amplifier A₃₁ without offset voltage connected in series. The output voltage of voltage source V_{OS1} can be equal to the offset voltage of the first stage amplifier. Without considering the offset voltage of the second stage amplifier, the connection mode of the other parts can be consistent with the example circuit of FIG. 6.

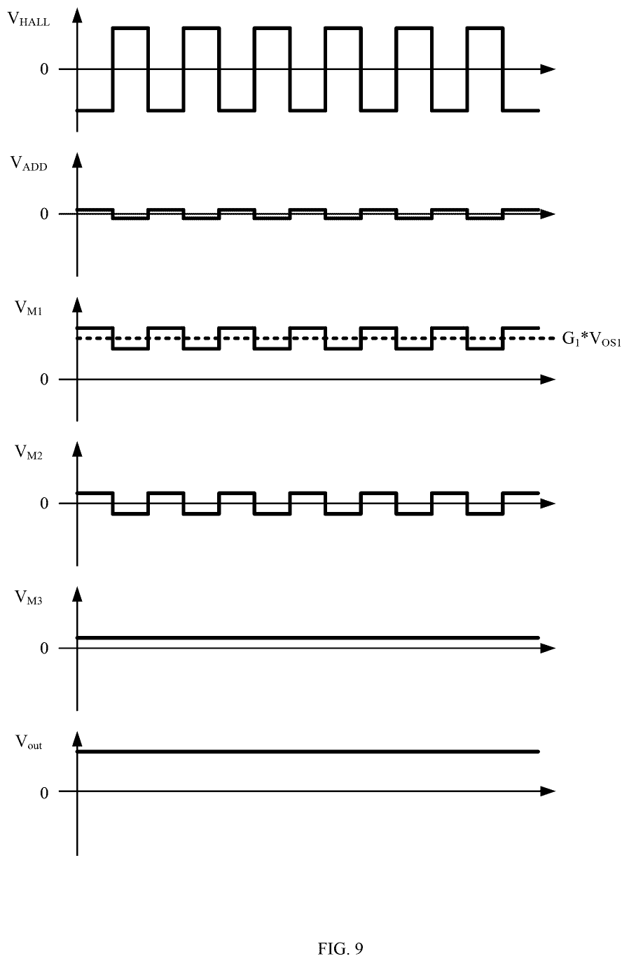

Referring now to FIG. 9, shown is a waveform diagram of an example equivalent circuit of the first instrumentation amplifier of FIG. 8, in accordance with embodiments of the present invention. The waveforms of sensor signal V_{HALL}, superimposed signal V_{ADD}, intermediate signal V_{M1}, intermediate signal V_{M2}, intermediate signal V_{M3}, and output signal Vout are shown in the example of FIG. 9. Superimposed signal V_{ADD} may be the signal provided to the first-stage amplifier after sensor signal V_{HALL} and feedback signal V_{f} are superposed. Here, without considering the offset voltage of the sensor itself, sensor signal V_{HALL} can be a square wave signal, and output signal Vout is a DC signal. After being modulated and demodulated by chopper CH₃₂, feedback signal V_{f} in feedback circuit 3c may be a square wave signal.

After sensor signal V_{HALL} and feedback signal Vf are superposed, superimposed signal V_{ADD} (e.g., voltage between nodes d₃ and d₄) may also be a square wave signal. Superimposed signal V_{ADD} and offset voltage V_{OS1} can be input to amplifier A₃₁, which may output intermediate signal V_{M1} after the amplification for superimposed signal V_{ADD} and offset voltage V_{OS1}. In addition, the first intermediate signal may have both AC and DC components, whereby DC component is G₁*V_{OS1}, and G₁ is the gain of the first stage amplifier. Intermediate signal V_{M1} can be filtered by high-pass filter circuit 3a to obtain intermediate signal V_{M2}. Chopper CH₃₁ may perform chopper modulation and demodulation on intermediate signal V_{M2} to obtain intermediate signal V_{M3} (e.g., a DC signal). Intermediate signal V_{M3} can be amplified by second stage amplifier 3b to obtain output signal Vₒᵤₜ. Thus, the signal associated with the offset voltage of first-stage amplifier A₃₁ and included in intermediate signal V_{M1} can be eliminated by the first high-pass filter circuit.

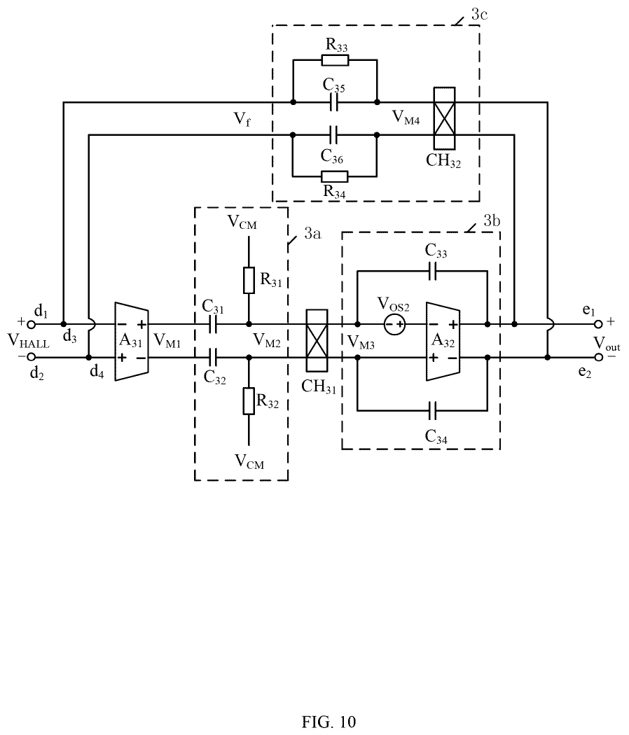

Referring now to FIG. 10, shown is another equivalent circuit of the first instrumentation amplifier, in accordance with embodiments of the present invention. In this particular example, the operational amplifier with offset voltage may be equivalent to the series connection of voltage source V_{OS2} and operational amplifier A₃₂ without offset voltage. The output voltage of voltage source V_{OS2} can be equal to the offset voltage of the operational amplifier. Without considering the offset voltage of the first stage amplifier, the connection mode of the other parts may be consistent with the example circuit of FIG. 6.

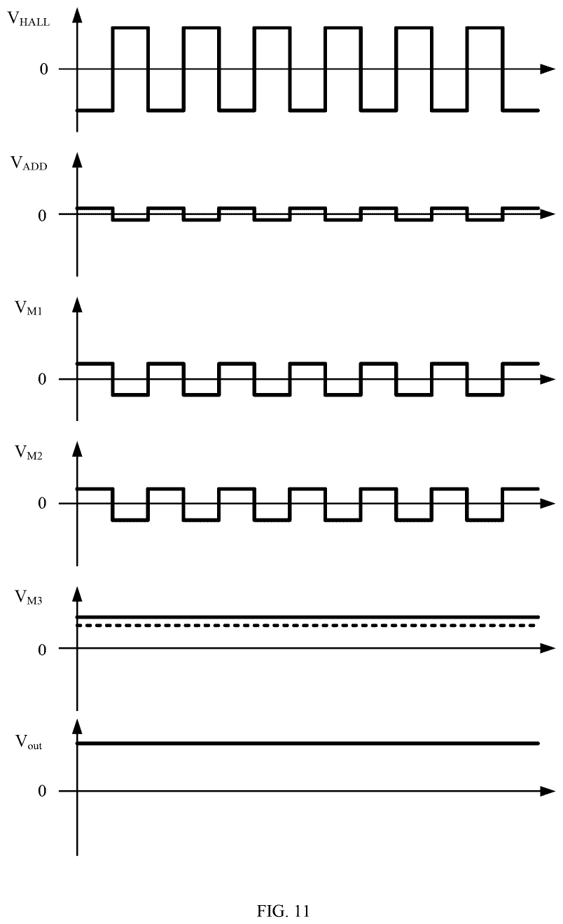

Referring now to FIG. 11, shown is a waveform diagram of another equivalent circuit of the first instrumentation amplifier of FIG. 10, in accordance with embodiments of the present invention. The waveforms of sensor signal V_{HALL}, superimposed signal V_{ADD}, intermediate signal V_{M1}, intermediate signal V_{M2}, intermediate signal V_{M3}, and output signal Vₒᵤₜ are shown in the example of FIG. 11. Here, without considering the offset voltage of the sensor itself, sensor signal V_{HALL} is a square wave signal, output signal Vₒᵤₜ can be a DC signal, and after being modulated and demodulated by chopper CH₃₂, feedback signal V_{f} in feedback circuit 3c can be a square wave signal. Due to the existence of voltage source V_{OS2}, the loop may adjust its operating point, and generate a compensation signal at the input and output terminals of the first-stage amplifier. The compensation signal at the output terminals of the first-stage amplifier can be close to the absolute value of voltage source V_{OS2} (e.g., almost equal thereto), and the direction of the compensation signal can be opposite to that of voltage source V_{OS2} (e.g., one being positive and the other negative). Correspondingly, the compensation signal at the input terminals of the first-stage amplifier can be equal to a ratio of the compensation signal and the gain of the first stage amplifier.

Therefore, superimposed signal V_{ADD} may be the signal generated by the superposition of sensor signal V_{HALL}, feedback signal V_{f} and the compensation signal at the input terminals of the first-stage amplifier, and superimposed signal V_{ADD} (e.g., the voltage between nodes d₃ and d₄) may also be a square wave signal. After superimposed signal V_{ADD} is input to first-stage amplifier A₃₁, first-stage amplifier A₃₁ may amplify the superimposed signal and output intermediate signal V_{M1}. At this time, intermediate signal V_{M1} can be obtained as follows: V_{M1}=G₁*(V_{HALL}+V_{f})+V_{com}, where V_{com} is the compensation signal. Intermediate signal V_{M1} can pass through the first high-pass filter circuit to obtain intermediate signal V_{M2}, and intermediate signal V_{M2} may pass through the first chopper to obtain intermediate signal V_{M3}. As shown in the waveform corresponding to intermediate signal V_{M3}, the waveform with the solid line is intermediate signal V_{M3}, and the waveform with the dotted line is the signal corresponding to the compensation signal in intermediate signal V_{M3} at the output terminal of the first stage amplifier; that is, compensation signal V_{com} at the output terminal of the first stage amplifier. The absolute value of compensation signal V_{com} can be close to that of second voltage source V_{OS2} (e.g., almost equal thereto), and the direction of compensation signal V_{com} may be opposite to that of voltage source V_{OS2}. Most of the voltage of voltage source V_{OS2} can be canceled, and the un-canceled part of the voltage of voltage source V_{OS2} may be inversely proportional to gain G₁ of the first stage amplifier. Because gain G₁ is large, the un-canceled part of the voltage of voltage source V_{OS2} can effectively be ignored. As such, the offset voltage of the second stage amplifier can be removed.

The instrumentation amplifier of particular embodiments may receive the sensor signal through the input port. The first-stage amplifier can amplify the sensor signal to obtain the first intermediate signal. The first high-pass filter circuit may eliminate the signal associated with the offset voltage of the first-stage amplifier and included in the first intermediate signal to obtain the second intermediate signal. The first chopper can perform chopper modulation and demodulation on the second intermediate signal to obtain the third intermediate signal. The second-stage amplifier may amplify the third intermediate signal to generate the output signal. The feedback circuit can the output signal back to the first-stage amplifier. Therefore, the offset voltage of the first stage amplifier can be eliminated by the first high-pass filter circuit, which may reduce the complexity of the circuit, the circuit area, and power consumption.

In addition, most of the offset voltage of the second stage amplifiers can be eliminated by using the loop formed of feedback circuit 3c and the first and second stage amplifiers. In the first example shown in FIGS. 6-11, the offset voltage of the sensor may not be considered, but as shown in FIG. 5, the sensor itself may have a certain offset voltage. Therefore, in order to further improve the accuracy of the instrumentation amplifier, particular embodiments may also provide another instrumentation amplifier.

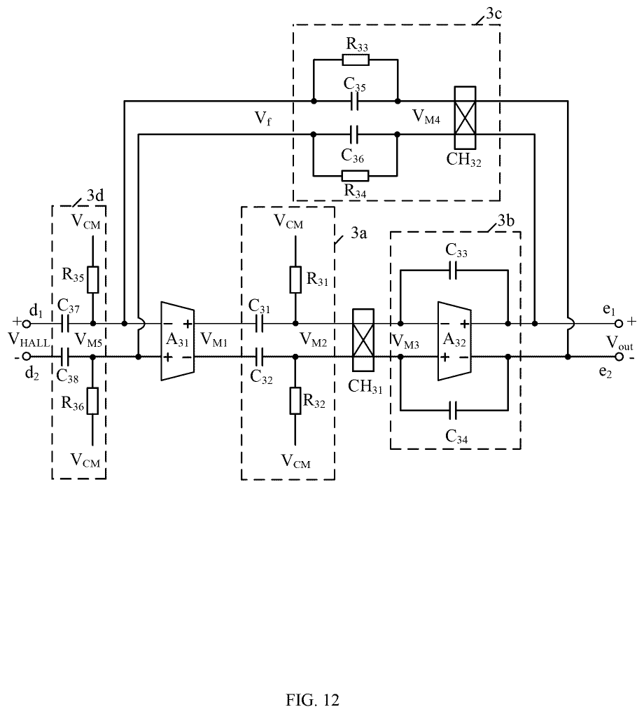

Referring now to FIG. 12, shown is a circuit diagram of a second example instrumentation amplifier, in accordance with embodiments of the present invention. In this particular example, the instrumentation amplifier can also include high-pass filter circuit 3d. High-pass filter circuit 3d can connect between the input port and amplifier A₃₁, and may eliminate the signal associated with the offset voltage of the sensor and included in the sensor signal. High-pass filter circuit 3d can include the second capacitor and the second impedance circuit. The second capacitor can connect between one terminal of the input port and one input terminal of amplifier A₃₁, and the second impedance circuit and the second capacitor can connect in series between one terminal of the input port and the reference terminal. In particular embodiments, high-pass filter circuit 3d can include capacitors C₃₇ and C₃₈, and impedance circuits R₃₅ and R₃₆. Capacitor C₃₇ can connect between positive input terminal d₁ and the inverting input terminal of amplifier A₃₁, one terminal of impedance circuit R₃₅ can connect to the common end of capacitor C₃₇ and amplifier A₃₁, and the other terminal of impedance circuit R₃₅ can connect to the reference terminal. Capacitor C₃₈ can connect between negative input terminal d₂ and the non-inverting input terminal of first-stage amplifier A₃₁. One terminal of impedance circuit R₃₆ can connect to the common end of capacitor C₃₈ and amplifier A₃₁, and the other terminal of impedance circuit R₃₆ can connect to the reference terminal.

Here, the reference terminal may provide a reference voltage (e.g., common mode voltage V_{CM}), and the reference voltage can be set according to particular applications. In another example, the reference terminal can be the ground terminal, and the reference voltage may be 0. In another embodiment, switching circuit 2 and instrumentation amplifier 3 may be integrated in one chip, and the reference voltage can be equal to the supply voltage of the chip multiplied by a proportional coefficient. Since the first stage amplifier itself has an offset voltage, the offset voltage can be a DC component, so intermediate signal V_{M1} may have both DC and AC components. Therefore, the second capacitor and the second impedance circuit can be set as a high-pass filter to connect to the input terminals of first-stage amplifier A₃₁. Because the characteristic of the capacitor is isolated from the DC component, the offset voltage of the first-stage amplifier may not pass, and the effective AC component can pass, such that the signal associated with the offset voltage of first-stage amplifier A₃₁ and included in intermediate signal V_{M1} can be eliminated.

In another example, the second impedance circuit can be a resistive element. In yet another example, the second impedance circuit can be an active resistor (e.g., implemented by the circuit shown in FIG. 7). The instrumentation amplifier shown in FIG. 12 can simultaneously remove the offset voltage of the sensor, the offset voltage of the first amplifier, and the offset voltage of the second amplifier.

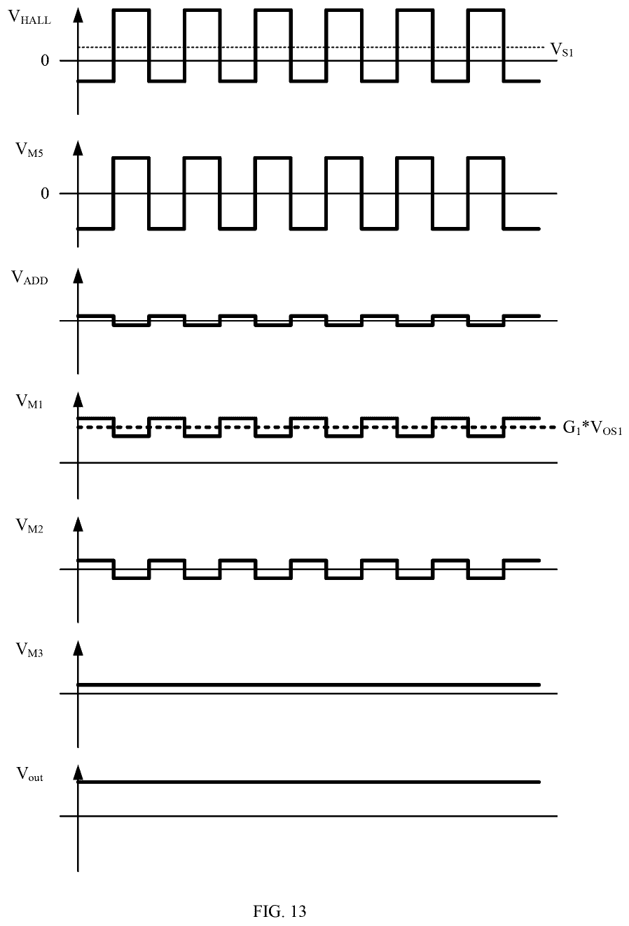

Referring now to FIG. 13, shown is a waveform diagram of the equivalent circuit of the second instrumentation amplifier, in accordance with embodiments of the present invention. The waveforms of sensor signal V_{HALL}, filtered sensor signal V_{M5}, superimposed signal V_{ADD}, intermediate signal V_{M1}, intermediate signal V_{M2}, intermediate signal V_{M3}, and output signal Vₒᵤₜ are shown. Due to offset voltage V_{S1} of the sensor, the average value of sensor signal V_{HALL} can be moved up offset voltage V_{S1} from 0V. That is, in the sensor signal read by the switching circuit, the offset voltage of sensor itself can be a DC signal, the output voltage of the sensor may be a high frequency signal, and the high frequency signal can be square wave. The sensor signal may be filtered by high-pass filter circuit 3d to obtain filtered sensor signal V_{M5}. Superimposed signal V_{ADD} may be provided to the first stage amplifier after filtered sensor signal V_{M5} and feedback signal V_{f} are superposed. Output signal Vₒᵤₜ can be a DC signal. Feedback signal V_{f} after being chopper modulated and demodulated by chopper CH₃₂ in feedback circuit 3c can be a square wave signal. Filtered sensor signal V_{M5} and feedback signal V_{f} may be superimposed to obtain superimposed signal V_{ADD}.

After superimposed signal V_{ADD} and offset voltage V_{OS1} are input to first-stage amplifier A₃₁, first-stage amplifier A₃₁ can output intermediate signal V_{M1} by amplifying superimposed signal V_{ADD} and offset voltage V_{OS1}. Intermediate signal V_{M1} may have both AC and DC components, and the DC component is G₁*V_{OS1}, where G₁ is the gain of the first-stage amplifier. Intermediate signal V_{M1} can be filtered by high-pass filter circuit 3a to obtain intermediate signal V_{M2}. Chopper CH₃₁ may perform chopper modulation and demodulation on intermediate signal V_{M2} to obtain intermediate signal V_{M3}, which can be a DC signal. Intermediate signal V_{M3} may be further amplified by stage amplifier 3b to obtain output signal Vₒᵤₜ. Thus, the signal included in the first intermediate signal and associated with the offset voltage of the first stage amplifier can be eliminated by the first high-pass filter circuit, and the part of the sensor signal associated with the offset voltage of the sensor can be eliminated by the second high-pass filter. For eliminating the offset voltage of the second-stage amplifier, the specific principle can be similar to that of FIGS. 10 and 11.

In particular embodiments may receive the sensor signal through the input port, the first-stage amplifier can amplify the sensor signal to obtain the first intermediate signal, and the first high-pass filter circuit may eliminate a part that is related to the offset voltage of the first-stage amplifier included in the first intermediate signal to obtain the second intermediate signal. Also, the first chopper may perform chopping modulation and demodulation on the second intermediate signal to obtain the third intermediate signal, the second stage amplifier can amplify the third intermediate signal to generate the output signal, and the feedback circuit may feed the output signal back to the first stage amplifier. Therefore, the offset voltage of the first-stage amplifier can be eliminated through the first high-pass filter circuit, thereby reducing the complexity of the circuit, and reducing the circuit area and power consumption. Further, the offset voltage of the sensor can be eliminated through the second high-pass filter circuit.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. An instrumentation amplifier, comprising:
a) an input port configured to receive a sensor signal, wherein the sensor signal is obtained by chopper modulating and demodulating an output voltage of a sensor;
b) a first-stage amplifier configured to amplify the sensor signal to obtain a first intermediate signal;
c) a first high-pass filter circuit, having input terminals coupled to output terminals of the first-stage amplifier, and being configured to eliminate a signal that is in the first intermediate signal and associated with an offset voltage of the first-stage amplifier, in order to obtain a second intermediate signal;
d) a first chopper, having input terminals coupled to output terminals of the first high-pass filter circuit, and being configured to perform chopper modulation and demodulation on the second intermediate signal to obtain a third intermediate signal;
e) a second-stage amplifier, having input terminals coupled to output terminals of the first chopper, and being configured to amplify the third intermediate signal to generate an output signal; and
f) a feedback circuit coupled between output terminals of the second-stage amplifier and the input terminals of the first-stage amplifier, and being configured to feed back the output signal to the first-stage amplifier.

2. The instrumentation amplifier of claim 1, wherein the first high-pass filter circuit comprises two first series structures, the first series structure comprising a first capacitor and a first impedance circuit coupled in series, wherein a first of the two first series structures is coupled between a first of the two output terminals of the first-stage amplifier and a reference terminal, and a second of the two first series structures is coupled between a second of the two output terminals of the first-stage amplifier and the reference terminal, wherein a compensation voltage is provided at the reference terminal.

3. The instrumentation amplifier of claim 2, wherein the first capacitor is coupled between a corresponding output terminal of the first-stage amplifier and the first chopper, and the first impedance circuit is coupled between a common node of the corresponding first capacitor and the first chopper and the reference terminal.

4. The instrumentation amplifier of claim 2, further comprising a second high-pass filter circuit coupled between the input port and the first stage amplifier, and being configured to eliminate a portion of the sensor signal that is associated with an offset voltage of the sensor.

5. The instrumentation amplifier of claim 4, wherein the second high-pass filter circuit comprises two second series structures, and the second series structure comprises a second capacitor and a second impedance circuit coupled in series, wherein a first of the two second series structures is coupled between a first of the two terminals of the input port and the reference terminal, and a second of the two second series structures is coupled between a second of the two terminals of the input port and the reference terminal.

6. The instrumentation amplifier of claim 5, wherein the second capacitor is coupled between a corresponding terminal of the input port and the first-stage amplifier, and the second impedance circuit is coupled between a common terminal of the corresponding first capacitor and the first-stage amplifier and the reference terminal.

7. The instrumentation amplifier of claim 5, wherein at least one of the first impedance circuit and the second impedance circuit is an active resistor.

8. The instrumentation amplifier of claim 7, wherein the active resistor comprises:
a) a first port;
b) a second port;
c) a first transistor;
d) a second transistor coupled in series with the first transistor between the first port and the second port; and
e) wherein the voltages at the control terminals of the first transistor and the second transistor are controlled such that the first transistor and the second transistor both operate in a sub-threshold region.

9. The instrumentation amplifier of claim 8, wherein when the first impedance circuit is configured as the active resistor, a first of the first port and the second port is coupled to a common node of the first capacitor and the first impedance circuit, and a second of the first port and the second port is coupled to the reference terminal.

10. The instrumentation amplifier of claim 8, wherein when the second impedance circuit is configured as the active resistor, a first of the first port and the second port is coupled to a common node of the second capacitor and the second impedance circuit, and a second of the first port and the second port is coupled to the reference terminal.

11. The instrumentation amplifier of claim 8, wherein the active resistor further comprises:
a) a first buffer;
b) a third transistor;
c) a first current source, coupled in series with the first buffer and the third transistor between the first port and a ground terminal;
d) a second buffer;
e) a fourth transistor;
f) a second current source coupled in series with the second buffer and the fourth transistor between the second port and the ground terminal; and
g) wherein control terminals of the first transistor and the third transistor are coupled to the first current source, and control terminals of the second transistor and the fourth transistor are coupled to the second current source;
h) wherein the third transistor is configured to generate a first bias voltage under the bias of a first bias current generated by the first current source, such that the first transistor operates in the sub-threshold region; and
i) wherein the fourth transistor is configured to generate a second bias voltage under the bias of a second bias current generated by the second current source, such that the second transistor operates in the sub-threshold region.

12. The instrumentation amplifier of claim 1, wherein the feedback circuit comprises:
a) a second chopper coupled to the output terminals of the second-stage amplifier, and being configured to perform chopper modulation and demodulation on the output signal to obtain a fourth intermediate signal;
b) two third capacitors;
c) two third resistors; and
d) wherein the third capacitor and the third resistor are coupled in parallel with between the output terminal of the second chopper and the input terminal of the first stage amplifier, and are configured to feed back the fourth intermediate signal to the first-stage amplifier.

13. The instrumentation amplifier of claim 1, wherein the second stage amplifier comprises:
a) an operational amplifier;
b) two fourth capacitors; and
c) wherein the two fourth capacitor are coupled between one output terminal and one input terminal of the operational amplifier.

14. The instrumentation amplifier of claim 12, further comprising a control circuit configured to generate a control signal to control an operating frequency of at least one of the first chopper and the second chopper to perform chopper modulation and demodulation.

15. A signal detection system, comprising the instrumentation amplifier of claim 1, and further comprising:
a) a sensor configured to generate an output voltage; and
b) a switching circuit configured to receive the output voltage to obtain a sensor signal corresponding to the output voltage of the sensor.
